(19) United States
(12) Patent Application Publication
(10) Pub. No.: US 2026/0293257 A1
(43) Pub. Date: Sep. 24, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Keisuke MIYAMOTO, Komatsu Ishikawa (JP); Tsuyoshi KACHI, Kanazawa Ishikawa (JP); Hiroaki KATOU, Nonoichi Ishikawa (JP)

(21) Appl. No.: 19/543,664

(22) Filed: Feb. 18, 2026

(30) Foreign Application Priority Data
Mar. 21, 2025 (JP) 2025-047303

(51) Int. Cl. H10D 64/00; H10D 30/66; H10D 62/10; H10D 30/01; H10D 62/60

(52) U.S. Cl. CPC H10D 64/112; H10D 30/665; H10D 30/668; H10D 62/107; H10D 64/117; H10D 30/0297; H10D 62/60

(57) ABSTRACT

A semiconductor device according to an embodiment includes a semiconductor layer, first and second field plate (FP) electrode groups, a gate electrode, a first insulating region, and a second insulating region. The semiconductor layer includes a cell region and a termination region. The FP electrode groups each include FP electrodes in the termination region. The gate electrode is between the first and second FP electrode groups. The conductive films are electrically connected to the FP electrodes of the FP electrode groups. The second insulating region is between the conductive films, and has a lower dielectric constant than the first insulating region.

### CROSS-REFERENCE TO RELATED APPLICATIONS

This application is based upon and claims the benefit of priority from Japanese Patent Application No. 2025-047303, filed March 21, 2025; the entire contents of which are incorporated herein by reference.

### FIELD

Embodiments relate to a semiconductor device.

### BACKGROUND

In semiconductor devices such as MOSFET (Metal Oxide Semiconductor Field Effect Transistor), it is preferable that the switching efficiency is improved.

### BRIEF DESCRIPTION OF THE DRAWINGS

FIG. 1 is a plan view of a semiconductor device according to the first embodiment.

FIG. 2 is an enlarged view of the area around the terminal region in FIG. 1.

FIG. 3 is a cross-sectional view along line A1-A1 in FIG. 1 of the semiconductor device according to the first embodiment.

FIG. 4 is a cross-sectional view along line B1-B1 in FIG. 1 of the semiconductor device according to the first embodiment.

FIG. 5 is a cross-sectional view along line C1-C1 in FIG. 1 of the semiconductor device according to the first embodiment.

FIG. 6A is a diagram corresponding to a cross-sectional view along line A1-A1 in FIG. 1 for explaining an example of a manufacturing process of a semiconductor device according to a first embodiment.

FIG. 6B is a diagram corresponding to a cross-sectional view along line B1-B1 in FIG. 1 for explaining an example of a manufacturing process of a semiconductor device according to a first embodiment.

FIG. 6C is a diagram corresponding to a cross-sectional view along line C1-C1 in FIG. 1 for explaining an example of a manufacturing process of a semiconductor device according to a first embodiment.

FIG. 7A is a diagram corresponding to a cross-sectional view along line A1-A1 in FIG. 1 for explaining an example of a manufacturing process of a semiconductor device according to a first embodiment.

FIG. 7B is a diagram corresponding to a cross-sectional view along line B1-B1 in FIG. 1 for explaining an example of a manufacturing process of a semiconductor device according to a first embodiment.

FIG. 7C is a diagram corresponding to a cross-sectional view along line C1-C1 in FIG. 1 for explaining an example of a manufacturing process of a semiconductor device according to a first embodiment.

FIG. 8A is a diagram corresponding to a cross-sectional view along line A1-A1 in FIG. 1 for explaining an example of a manufacturing process of a semiconductor device according to a first embodiment.

FIG. 8B is a diagram corresponding to a cross-sectional view along line B1-B1 in FIG. 1 for explaining an example of a manufacturing process of a semiconductor device according to a first embodiment.

FIG. 8C is a diagram corresponding to a cross-sectional view along line C1-C1 in FIG. 1 for explaining an example of a manufacturing process of a semiconductor device according to a first embodiment.

FIG. 9A is a diagram corresponding to a cross-sectional view along line A1-A1 in FIG. 1 for explaining an example of a manufacturing process of a semiconductor device according to a first embodiment.

FIG. 9B is a diagram corresponding to a cross-sectional view along line B1-B1 in FIG. 1 for explaining an example of a manufacturing process of a semiconductor device according to a first embodiment.

FIG. 9C is a diagram corresponding to a cross-sectional view along line C1-C1 in FIG. 1 for explaining an example of a manufacturing process of a semiconductor device according to a first embodiment.

FIG. 10 is a plan view of a semiconductor device according to a second embodiment.

FIG. 11 is an enlarged view of the area around the terminal region in FIG. 10.

FIG. 12 is a partial cross-sectional view along line A2-A2 in FIG. 10 of the semiconductor device according to a second embodiment.

FIG. 13 is a partial cross-sectional view along line B2-B2 in FIG. 10 of the semiconductor device according to a second embodiment.

FIG. 14 is a cross-sectional view along line C2-C2 in FIG. 10 of the semiconductor device according to a second embodiment.

FIG. 15A is a diagram corresponding to a cross-sectional view along line A2-A2 in FIG. 10 for explaining an example of a manufacturing process of a semiconductor device according to a second embodiment.

FIG. 15B is a diagram corresponding to a cross-sectional view along line B2-B2 in FIG. 10 for explaining an example of a manufacturing process of a semiconductor device according to a second embodiment.

FIG. 16 is a plan view of a semiconductor device according to a third embodiment.

FIG. 17 is an enlarged view of the area around the terminal region in FIG. 16.

FIG. 18 is a cross-sectional view along line A3-A3 in FIG. 16 of the semiconductor device according to a third embodiment.

FIG. 19 is a cross-sectional view along line B3-B3 in FIG. 16 of the semiconductor device according to a third embodiment.

FIG. 20 is a cross-sectional view along line D-D in FIG. 16 of the semiconductor device according to a third embodiment.

### DETAILED DESCRIPTION

According to one embodiment, a semiconductor device includes a semiconductor layer with a first main surface and a second main surface. The semiconductor layer has a cell region and a terminal region surrounding the cell region. A first field plate electrode group is in the terminal region of the semiconductor layer. The first field plate electrode group has a plurality of field plate electrodes, each extending in a first direction into the semiconductor layer from the second main surface with a first insulating region therebetween. The plurality of field plate electrodes of the first field plate group are spaced from one another along a second direction parallel to the second main surface. A second field plate electrode group is in the terminal region of the semiconductor layer. The second field plate electrode group has a plurality of field plate electrodes, each extending in the first direction into the semiconductor layer from the first main surface with a second insulating region therebetween. The plurality of field plate electrodes of the second field plate group are spaced from one another along the second direction. The second field plate electrode group is spaced from the first field plate electrode group in a third direction intersecting the second direction and parallel to the first main surface. A gate electrode faces the semiconductor layer via a third insulating region. The gate electrode is between the first field plate electrode group and the second field plate electrode group in the third direction. A fourth insulating region is on the second main surface in the terminal region of the semiconductor layer. A first conductive film is on the fourth insulating region and electrically connected to the field plate electrodes of the first field plate electrode group via a first contact portion. A second conductive film is on the fourth insulating region and electrically connected to the field plate electrodes of the second field plate electrode group via a second contact portion. A third conductive film is on the fourth insulating region. The third conductive film is between the first conductive film and the second conductive film in the third direction and is electrically connected to the gate electrode via a third contact portion. The third conductive film extends from the third contact portion in the second direction. A fifth insulating region is between the first conductive film and the third conductive film and the second conductive film and the third conductive film in the third direction. The fifth insulating region has a lower dielectric constant than the fourth insulating region.

The certain example embodiments of the present disclosure will be described below with reference to the drawings. These example embodiments do not limit the present disclosure. The drawings are schematic or conceptual, and the depicted dimensions and proportions of each part are not necessarily the same as those in reality. In the specification and drawings, the same reference symbols are given to elements substantially similar to those already described with reference to a previously mentioned drawing, and repeated descriptions of such elements may be omitted as appropriate.

For convenience of explanation, an XYZ orthogonal coordinate system may be adopted in the figures. In the present description, the Z-axis direction is taken as the stacking direction (thickness direction) of the semiconductor device. The source electrode side in the Z-axis direction may also referred to as "up," “upper,” or “upward,” and the drain electrode side may also be referred to as "down," “lower,” or “downward.” However, such descriptive expressions are for convenience and may be unrelated to the direction of gravity.

In the following description, the notations n+, n, n-, and p+, p, p- may be used to represent the relative concentrations levels of impurity (dopants) of each conductivity type. That is, n+ indicates that the n-type impurity concentration is relatively higher than n, and n- indicates that the n-type impurity concentration is relatively lower than n. Similarly, p+ indicates that the p-type impurity concentration is relatively higher than p, and p- indicates that the p-type impurity concentration is relatively lower than p. These notations represent the net impurity concentrations after compensation when both p-type and n-type impurities are included in each region. In the following description, n-type and p-type may be reversed.

The impurity concentration of the semiconductor region can be measured by secondary ion mass spectrometry (SIMS), for example. The relative high and low impurity concentrations can also be determined from the high and low carrier concentrations obtained by scanning capacitance microscopy (SCM), for example.

The thickness and other dimensions of a field plate insulating film or the like can be measured by surface and/or cross-sectional analysis using a transmission electron microscope (TEM), energy dispersive X-ray spectroscopy (EDX), or scanning electron microscope (SEM), for example.

In this specification, terms such as "same," "identical," "equal," etc., used to specify shapes, geometric conditions, physical properties, and their degrees, as well as dimensions and values of physical properties, are interpreted to include ranges that can be expected to have similar functions without being strictly bound by their exact meanings.

### FIRST EMBODIMENT

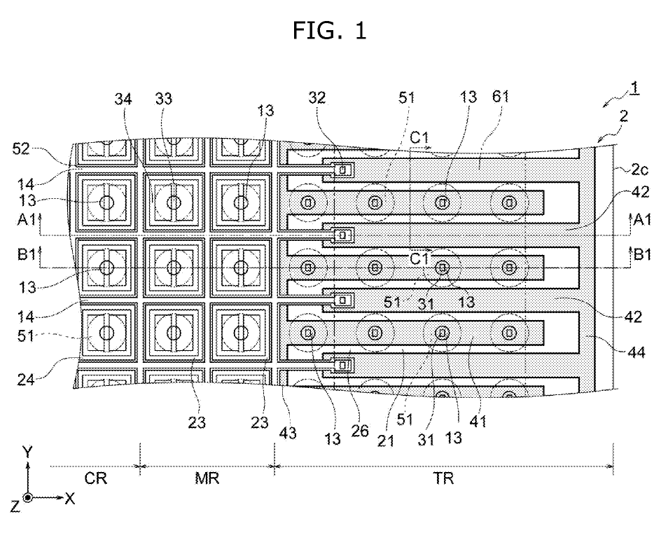

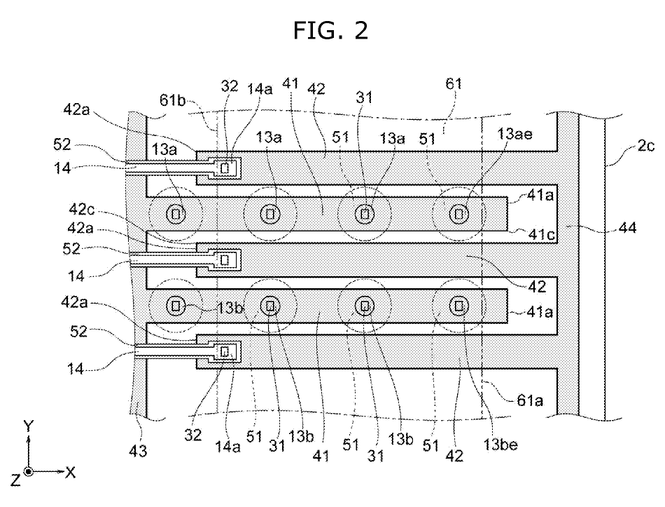

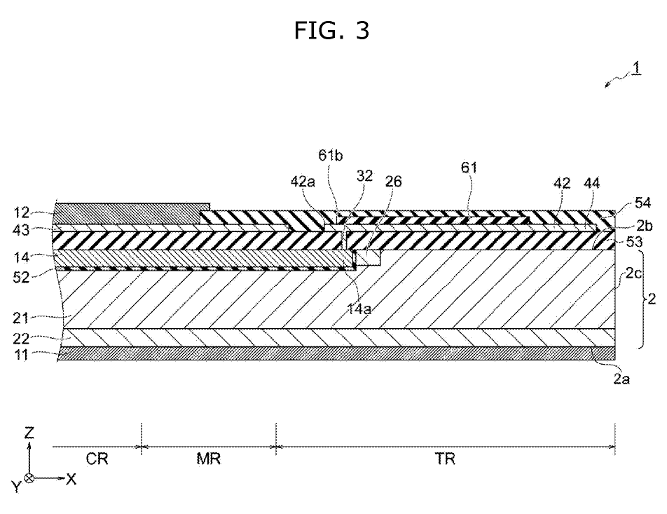

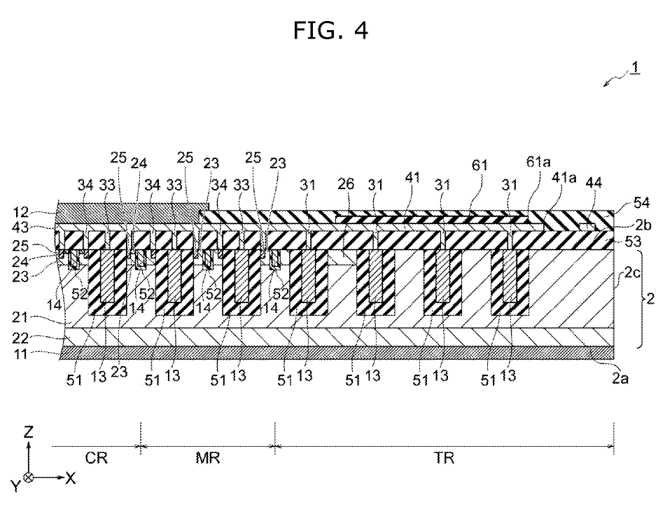

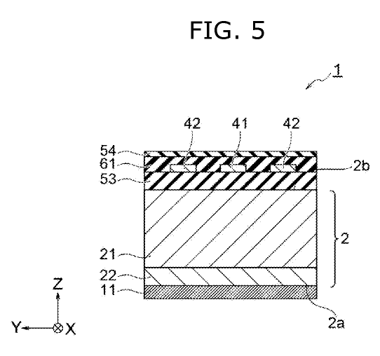

The semiconductor device 1 according to the first embodiment will be described with reference to FIGS. 1 to 5. FIG. 1 is a plan view of the semiconductor device 1 according to the first embodiment. FIG. 2 is an enlarged view of the terminal region TR in FIG. 1. FIG. 3 is a cross-sectional view along line A1-A1 in FIG. 1 of the semiconductor device 1 according to the first embodiment. FIG. 4 is a cross-sectional view along line B1-B1 in FIG. 1 of the semiconductor device 1 according to the first embodiment. FIG. 5 is a cross-sectional view along line C1-C1 in FIG. 1 of the semiconductor device 1 according to the first embodiment. In FIGS. 1 and 2, the source electrode 12, insulating region 53, and insulating region 54 are omitted from the depiction. Furthermore, in FIG. 1, the high concentration region 25 and conductive film 43 in the cell region CR and intermediate region MR are also omitted.

The semiconductor device 1 is, for example, a vertical MOSFET. The semiconductor device 1 may instead be a transistor, such as an IGBT (Insulated Gate Bipolar Transistor), or a diode. The semiconductor device 1 may be a vertical device or a horizontal device. The following description will use the example of the semiconductor device 1 being a vertical MOSFET.

First, the planar structure of the semiconductor device 1 according to the first embodiment will be described. In the plane shown in FIG. 1, the semiconductor device 1 includes a semiconductor layer 2, field plate electrodes 13 (FP electrodes 13), a gate electrode 14, a drift region 21, a base region 23, a source region 24, a guard ring region 26, contact portions 31, contact portions 32, contact portions 33, contact portions 34, conductive films 41, conductive films 42, conductive films 43, conductive films 44, insulating regions 51, insulating regions 52, and insulating regions 61.

Various semiconductor regions, such as the drift region 21, are provided in the semiconductor layer 2. In the present embodiment, the semiconductor layer 2 includes the cell region CR, intermediate region MR, and terminal region TR.

The terminal region TR is a region extending inward from the side portion 2c of the semiconductor layer 2. The terminal region TR is provided to surround the cell region CR in a plane orthogonal to the Z-axis direction.

The cell region CR is a region located inside the semiconductor layer 2, more inward than the terminal region TR in a plane orthogonal to the Z-axis direction. The cell region CR includes the base region 23 and the source region 24, and it is also a current region where the current flows between the drain electrode 11 and the source electrode 12. The cell region CR is, for example, located at the center of the semiconductor device 1 in a plane orthogonal to the Z-axis direction.

The intermediate region MR is a region located between the cell region CR and the terminal region TR. The intermediate region MR is provided to surround the cell region CR, for example. The intermediate region MR is provided with the gate electrode 14 and the base region 23, but the source region 24 is not provided therein. By providing such an intermediate region MR, the breakdown voltage of the semiconductor device 1 can be improved.

In the example of FIG. 1, two FP electrodes 13 are arranged along the X-axis direction in the intermediate region MR. However, this is not a limitation, and any number of FP electrodes 13 may be arranged along the X-axis direction in the intermediate region MR. A single FP electrode 13 may be provided in some examples. In some examples, the intermediate region MR may not be provided at all, and the cell region CR may be in contact with the terminal region TR.

Multiple FP electrodes 13 are arranged in a dot pattern across the cell region CR, intermediate region MR, and terminal region TR of the semiconductor layer 2. In this example, each FP electrode 13 is arranged at a predetermined interval along the X-axis and Y-axis directions. Insulating regions 51 are provided around each FP electrode 13. The FP electrodes 13 and insulating regions 51 are provided in field plate trenches (FP trenches) arranged in a dot pattern within the semiconductor layer 2. That is, the semiconductor device b is formed with multiple FP trenches arranged at predetermined intervals, and FP electrodes 13 and insulating regions 51 are formed within each FP trench.

In the cell region CR, high concentration regions 25 (FIG. 4) are provided around the insulating regions 51, and source regions 24 are provided around the high concentration regions 25. In the intermediate region MR, high concentration regions 25 are provided around the insulating regions 51, and base regions 23 are provided around the high concentration regions 25. In the terminal region TR, drift regions 21 or guard ring regions 26 are provided around the insulating regions 51. In this embodiment, the X-axis position (X coordinate) of the boundary between the drift region 21 and the guard ring region 26 is approximately the same as the X coordinate of the third FP electrode 13 from the right in FIG. 1. However, the position of the boundary between the drift region 21 and the guard ring region 26 is not limited to this example and can be arbitrarily set.

The gate electrode 14 is mainly provided in the cell region CR and the intermediate region MR of the semiconductor layer 2 via the insulating region 52. As shown in FIG. 1, the gate electrode 14 extends in the X-axis and Y-axis directions in the cell region CR and the intermediate region MR, respectively, and is provided to define sections that include each FP electrode 13 provided in the cell region CR and the intermediate region MR. In this embodiment, the gate electrode 14 in the cell region CR is provided to surround the source region 24 via the insulating region 52. The gate electrode 14 in the intermediate region MR is provided to surround the base region 23 via the insulating region 52.

The gate electrode 14 extends along the X-axis direction to the middle of the terminal region TR from an intersection of a part extending in the X-axis direction and a part extending in the Y-axis direction at the boundary between the intermediate region MR and the terminal region TR. The end of the part extending to the middle of the terminal region TR is electrically connected to the contact portion 32. The contact portion 32 is electrically connected to a conductive film 42. That is, the gate electrode 14 is electrically connected to a conductive film 42 via the contact portion 32. The conductive films 42 extend in the X-axis direction and are electrically connected to each other by the conductive film 44 extending in the Y-axis direction near the side portion 2c. The conductive film 44 is electrically connected to a gate pad, for example.

The contact portion 31 electrically connects a FP electrode 13 provided in the terminal region TR to a conductive film 41. The conductive films 41 are electrically connected to each other by the conductive film 43 provided in the cell region CR and the intermediate region MR. The conductive film 43 is electrically connected to the source electrode 12. The conductive film 43 is also electrically connected to the contact portions 33 and 34. The contact portion 33 is electrically connected to the FP electrode 13, the base region 23, and the high concentration region 25 in the cell region CR and the intermediate region MR. The contact portion 34 is electrically connected to the source region 24 and the high concentration region 25 in the cell region CR, and to the base region 23 and the high concentration region 25 in the intermediate region MR.

In this embodiment, the contact portions 33 and 34 have the planar shapes shown in FIG. 1. More specifically, the contact portion 34 is provided in a rectangular frame shape along the outer edge of the rectangular section defined by the gate electrode 14 extending in the X-axis and Y-axis directions. The contact portion 33 connects the middle parts of the portions extending in the X-axis direction of each contact portion 34. That is, the contact portion 33 is provided to divide the rectangular area defined by the contact portion 34 into two areas arranged in the X-axis direction. The middle part of each contact portion 33 in the Y-axis direction is located above the FP electrode 13.

The insulating region 61 covers the conductive film 41 and the conductive film 42 in the terminal region TR. The insulating region 61 is an example of a fifth insulating region.

Next, with reference to FIG. 2, the area around the terminal region TR of the semiconductor layer 2 will be described. As shown in FIG. 2, the FP electrodes 13 provided in the terminal region TR constitute a first field plate electrode group (first FP electrode group) including multiple FP electrodes 13a, and a second field plate electrode group (second FP electrode group) including multiple FP electrodes 13b. That is, the first FP electrode group includes the FP electrodes 13a arranged in the X-axis direction. The second FP electrode group similarly includes the FP electrodes 13b arranged in the X-axis direction. The second FP electrode group is adjacent to the first FP electrode group in the Y-axis direction.

The FP electrode 13ae is the FP electrode at the end near the side portion 2c among the FP electrodes 13a included in the first FP electrode group. In other words, the FP electrode 13ae is the FP electrode closest to the side portion 2c of the semiconductor layer 2 among the FP electrodes 13a included in the first FP electrode group. The FP electrode 13be is similarly the FP electrode arranged at the end near the side portion 2c among the FP electrodes 13b included in the second FP electrode group.

Multiple FP electrodes 13a included in the first FP electrode group are electrically connected to the conductive film 41. More specifically, the conductive film 41 is provided to extend in the X-axis direction above the first FP electrode group. The conductive film 41 is electrically connected to each FP electrode 13a via a contact portion 31. The conductive film 41 electrically connected to each FP electrode 13a is an example of a first conductive film. The contact portion 31 electrically connecting the conductive film 41 to each FP electrode 13a is an example of a first contact portion.

Similarly, multiple FP electrodes 13b included in the second FP electrode group are electrically connected to the conductive film 41. More specifically, the conductive film 41 is provided to extend in the X-axis direction above the second FP electrode group. The conductive film 41 is electrically connected to each FP electrode 13b via a contact portion 31. The conductive film 41 electrically connected to each FP electrode 13b is an example of a second conductive film. The contact portion 31 electrically connecting the conductive film 41 to each FP electrode 13b is an example of a second contact portion.

The gate electrode 14 in the terminal region TR is arranged between the first FP electrode group and the second FP electrode group in the Y-axis direction. The gate electrode 14 includes an end portion 14a. The end portion 14a of the gate electrode 14 is electrically connected to the conductive film 42 via the contact portion 32. The conductive film 42 extends from the contact portion 32 towards the side portion 2c. More specifically, the conductive film 42 is provided above the gate electrode 14 and is positioned between the conductive film 41 (first conductive film) electrically connected to the FP electrode 13a and the conductive film 41 (second conductive film) electrically connected to the FP electrode 13b in the Y-axis direction. The conductive film 42 is an example of a third conductive film. The contact portion 32 is an example of a third contact portion.

The conductive film 41 and the conductive film 42 are alternately provided along the Y-axis direction. Multiple conductive films 41 are connected to the conductive film 43, and multiple conductive films 42 are connected to the conductive film 44. In other words, the conductive films 41 to 44 constitute a comb-shaped wiring layer in the terminal region TR. With a comb-shaped wiring layer, it is possible to position the FP electrodes 13 closer to the side portion 2c, thereby improving the breakdown voltage of the semiconductor device 1.

The conductive film 42 is electrically coupled to the opposing conductive film 41 in the Y-axis direction. That is, a certain capacitance (parasitic capacitance) exists between the adjacent conductive film 41 and conductive film 42 in the Y-axis direction.

The insulating region 61 is provided to cover the conductive film 41 and the conductive film 42. In this first embodiment, the end portion 61a on the side portion 2c side (terminal region TR side) of the insulating region 61 is positioned closer to the cell region CR side than the end portion 41a of the conductive film 41. That is, the corner portion 41c of the conductive film 41 is not covered by the insulating region 61. In this first embodiment, the corner portion 41c is covered by the insulating region 54 (FIG. 4), which has a higher dielectric constant than the insulating region 61. The end portion 61a may be positioned closer to the side portion 2c side than the end portion 41a. The end portion 61a is an example of a first end portion.

The end portion 61b on the cell region CR side of the insulating region 61 is positioned closer to the side portion 2c side than the end portion 42a on the cell region CR side of the conductive film 42. That is, the corner portion 42c of the conductive film 42 is not covered by the insulating region 61. In this embodiment, the corner portion 42c of the conductive film 42 is covered by the insulating region 54, which has a higher dielectric constant than the insulating region 61. The end portion 61b may be positioned closer to the cell region CR side than the end portion 42a. The end portion 61b is an example of a second end portion.

The end portion 61a is positioned above the insulating region 51 between the FP electrode 13ae and the semiconductor layer 2. That is, the X coordinate of the end portion 61a is the same as the X coordinate of the insulating region 51 surrounding the FP electrode 13ae. The end portion 61a is also positioned above the insulating region 51 between the FP electrode 13be and the side portion 2c.

The end portion 61b is positioned between the end portion 42a and the contact portion 32 in the X-axis direction. However, in other examples, the end portion 61b may be positioned closer to the side portion 2c side than the contact portion 32 in the X-axis direction.

The FP electrodes 13a included in the first FP electrode group and the FP electrodes 13b included in the second FP electrode group are arranged along the Y-axis direction. However, the FP electrodes 13a included in the first FP electrode group and the FP electrodes 13b included in the second FP electrode group may be arranged obliquely to the X-axis direction in some examples. In this case, the X coordinate of the end portion 41a on the side portion 2c side of the conductive film 41 may vary for each conductive film 41. For example, the X coordinate of the end portion 41a of the conductive film 41 (first conductive film) electrically connected to the FP electrode 13a may differ from the X coordinate of the end portion 41a on the side portion 2c side of the conductive film 41 (second conductive film) electrically connected to the FP electrode 13b.

Next, with reference to FIGS. 3 to 5, the cross-sectional structure of the semiconductor device 1 according to the first embodiment will be described. As shown in FIGS. 3 to 5, the semiconductor device 1 includes a semiconductor layer 2, a drain electrode 11, a source electrode 12, contact portions 31, 32, 33, 34, conductive films 41, 42, 43, 44, insulating regions 53, insulating regions 54, and insulating regions 61.

The semiconductor layer 2 is provided between the drain electrode 11 and the source electrode 12. The semiconductor layer 2 has a lower surface 2a, an upper surface 2b, and a side portion 2c connecting the lower surface 2a and the upper surface 2b. The lower surface 2a and the upper surface 2b are examples of a first main surface and a second main surface.

The semiconductor layer 2 may be an epitaxial layer, a semiconductor substrate, or a semiconductor substrate with an epitaxial layer disposed thereon. In this first embodiment, the semiconductor layer 2 is silicon (Si). In this case, arsenic (As), phosphorus (P), or antimony (Sb) may be used as the n-type impurity, and boron (B) may be used as the p-type impurity. In other examples, semiconductor layer 2 may also be composed of compound semiconductors such as silicon carbide (SiC) or gallium nitride (GaN).

The drain electrode 11 functions as the drain electrode of the MOSFET. The drain electrode 11 is provided on the lower surface 2a of the semiconductor layer 2. The drain electrode 11 is in ohmic contact with the drain region 22, for example. The drain electrode 11 includes at least one of copper (Cu), titanium (Ti), tungsten (W), and aluminum (Al). The drain electrode 11 is an example of a first electrode.

The source electrode 12 functions as the source electrode of the MOSFET. The source electrode 12 is provided on the upper surface 2b of the semiconductor layer 2 via the conductive film 43 and the insulating region 53. In this embodiment, the source electrode 12 is provided on the upper surface 2b of the semiconductor layer 2 in the cell region CR and the intermediate region MR. The source electrode 12 is in contact with the conductive film 43 and is electrically connected to the conductive film 43. The source electrode 12 can be at least one of copper (Cu), titanium (Ti), tungsten (W), and aluminum (Al). The source electrode 12 is an example of a second electrode.

As shown in FIG. 4, the contact portion 31 is provided on the upper surface 2b of the semiconductor layer 2 in the terminal region TR. More specifically, the upper end of the contact portion 31 is connected to the conductive film 41. The lower end of the contact portion 31 penetrates the insulating region 53 in the Z-axis direction and contacts a FP electrode 13 in the terminal region TR. The contact portion 31 electrically connects the FP electrode 13 in the terminal region TR to the conductive film 41.

As shown in FIG. 3, the contact portion 32 is provided on the upper surface 2b of the semiconductor layer 2 in the terminal region TR. More specifically, the upper end of the contact portion 32 is connected to the conductive film 42. The lower end of the contact portion 32 penetrates the insulating region 53 in the Z-axis direction and contacts the end portion 14a of the gate electrode 14 in the terminal region TR. The contact portion 32 electrically connects a gate electrode 14 to the conductive film 42.

As shown in FIG. 4, the contact portion 33 is provided on the upper surface 2b of the semiconductor layer 2 in the cell region CR and the intermediate region MR. More specifically, the upper end of the contact portion 33 is connected to the conductive film 43. The lower end of the contact portion 33 penetrates the insulating region 53 in the Z-axis direction and contacts the FP electrode 13 provided in the cell region CR and the intermediate region MR. The contact portion 31 electrically connects a FP electrode 13 in the cell region CR or the intermediate region MR to the conductive film 43.

The contact portion 34 is provided on the upper surface 2b of the semiconductor layer 2 in the cell region CR and the intermediate region MR. More specifically, the upper end of the contact portion 34 is connected to the conductive film 43. The lower end of the contact portion 34 penetrates the insulating region 53 in the Z-axis direction and contacts the high concentration region 25 provided in the cell region CR and the intermediate region MR. The contact portion 34 electrically connects a high concentration region 25 in the cell region CR or the intermediate region MR to the conductive film 43. The lower end of the contact portion 34 also contacts the source region 24 in the cell region CR. The contact portion 34 electrically connects the source region 24 in the cell region CR to the conductive film 43.

As shown in FIGS. 4 and 5, the conductive film 41 is provided on the insulating region 53 in the terminal region TR and extends in the X-axis direction. The conductive film 41 comprises at least one of tungsten (W), copper (Cu), titanium (Ti), and aluminum (Al). The FP electrode 13 provided in the terminal region TR is electrically connected to the conductive film 41 via the contact portion 31.

As shown in FIGS. 3 and 5, the conductive film 42 is provided on the insulating region 53 in the terminal region TR and extends in the X-axis direction. The conductive film 42 comprises at least one of tungsten (W), copper (Cu), titanium (Ti), and aluminum (Al).

As shown in FIGS. 3 and 4, the conductive film 43 is provided on the insulating region 53 in the cell region CR and the intermediate region MR. The conductive film 43 comprises at least one of tungsten (W), copper (Cu), titanium (Ti), and aluminum (Al).

The conductive film 44 is provided on the insulating region 53 in the terminal region TR. The conductive film 43 comprises at least one of tungsten (W), copper (Cu), titanium (Ti), and aluminum (Al).

As shown in FIGS. 3 to 5, the insulating region 53 is provided on the upper surface 2b of the semiconductor layer 2 in the cell region CR, the intermediate region MR, and the terminal region TR. The insulating region 53 is a so-called interlayer insulating film. The insulating region 53 includes, for example, silicon oxide or silicon nitride. The insulating region 53 is an example of a fourth insulating region.

The insulating region 54 is provided on the insulating region 53 in the intermediate region MR and the terminal region TR. The insulating region 54 is a so-called interlayer insulating film. The insulating region 54 may also be provided on the insulating region 53 in a part of the cell region CR where the source electrode 12 is not present. The insulating region 54 comprises, for example, silicon oxide or silicon nitride. The insulating region 54 is an example of a sixth insulating region.

The insulating region 61 is provided on the insulating region 53 in the terminal region TR. As shown in FIG. 5, the insulating region 61 is positioned between the conductive film 41 and the conductive film 42 in the Y-axis direction. In this first embodiment, the insulating region 61 embeds (covers) the conductive film 41 and the conductive film 42. That is, the insulating region 61 is provided not only between the conductive film 41 and the conductive film 42 in the Y-axis direction but also above the conductive film 41 and the conductive film 42. As shown in FIGS. 3 to 5, the insulating region 54 is provided above the insulating region 61 wherever the insulating region 61 is provided. That is, where the insulating region 61 is provided, the insulating region 54 is not in direct contact with the conductive film 41 and the conductive film 42. In other words, the semiconductor device 1 according to the present embodiment has a structure in which part of the insulating region 54 is replaced by the insulating region 61, which is a low dielectric constant film.

The insulating region 61 is a low dielectric constant film having a dielectric constant lower than the insulating region 53. For example, if the insulating region 53 is a silicon oxide film, the insulating region 61 is made of a material with a lower dielectric constant than the silicon oxide film. Examples of films with a lower dielectric constant than the silicon oxide film include a carbon-added silicon oxide film (carbon-doped silicon oxide film), a fluorine-added silicon oxide film (fluorine-doped silicon oxide film), or a resist film. The carbon-added silicon oxide film and the fluorine-added silicon oxide film each contain carbon-added silicon oxide (SiOC) or fluorine-added silicon oxide (SiOF), respectively. In this context, a resist film is an insulating film comprising organic polymer materials such as polyimide.

In the above description, the comparison target of the dielectric constant of the insulating region 61 was the insulating region 53. However, the comparison target of the dielectric constant of the insulating region 61 is not limited to this and may be the insulating region 51, the insulating region 52, or the insulating region 54. For example, the insulating region 61 may be provided as a film with a lower dielectric constant than the insulating region 54.

Next, an example of the internal structure of the semiconductor layer 2 will be described. The internal structure of the semiconductor layer 2 in other examples is not limited to the description below.

As shown in FIGS. 3 to 5, the semiconductor layer 2 is provided with FP electrodes 13, gate electrodes 14, drift regions 21, drain regions 22, base regions 23, source regions 24, high concentration regions 25, guard ring regions 26, insulating regions 51, and insulating regions 52.

As shown in FIG. 4, each FP electrode 13 is provided in a columnar shape in the drift region 21 via the insulating region 51. Each FP electrode 13 is electrically insulated from the semiconductor layer 2 by the insulating region 51. The FP electrodes 13 provided in the cell region CR and the intermediate region MR are electrically connected to the source electrode 12 via a contact portion 33 and the conductive film 43. The FP electrodes 13 provided in the terminal region TR are electrically connected to the source electrode 12 via a contact portion 31, the conductive film 41, and the conductive film 43. The FP electrodes 13 are made of polysilicon containing p-type or n-type impurities, for example. By providing the FP electrodes 13, when the semiconductor device 1 is in the off state, the reverse voltage applied between the drain electrode 11 and the source electrode 12 causes a depletion layer to extend from the insulating region 51 where the FP electrodes 13 are arranged to the surrounding drift region 21. By connecting this depletion layer to the depletion layer extending from the insulating region 51 where the adjacent FP electrodes 13 are arranged, the breakdown voltage of the semiconductor device 1 can be improved (increased).

The insulating region 51 is provided in the drift region 21, and the FP electrode 13 is arranged inside it. In this embodiment, the insulating region 51 is located on the inner wall of the FP trench where the FP electrode 13 is provided, that is, below and beside the FP electrode 13. The insulating region 51 comprises, for example, silicon oxide or silicon nitride. The insulating region 51 is an example of a first insulating region and a second insulating region.

As shown in FIGS. 3 and 4, the gate electrode 14 functions as the gate electrode of the MOSFET. The gate electrode 14 is provided to face the base region 23 via the insulating region 52 in the X-axis direction or the Y-axis direction. The gate electrode 14 also faces the semiconductor layer 2 (in this embodiment, the drift region 21) via the insulating region 52 in the Z-axis direction. The gate electrode 14 is provided inside the insulating region 52. The gate electrode 14 is electrically insulated from the semiconductor layer 2 by the insulating region 52. The gate electrode 14 is made of polysilicon containing p-type or n-type impurities, for example. When a voltage is applied to the gate electrode 14, a channel is formed in the base region 23 facing the gate electrode 14, and carriers (in this example, electrons) flow between the drift region 21 (drain region 22) and the source region 24. This turns the MOSFET on.

The insulating region 52 is provided in the base region 23 and the source region 24, electrically insulating the gate electrode 14 from the semiconductor layer 2. In this embodiment, the insulating region 52 is located on the inner wall of the gate trench where the gate electrode 14 is provided, that is, below and beside the gate electrode 14. The insulating region 52 comprises, for example, silicon oxide or silicon nitride. The insulating region 52 is an example of a third insulating region.

Therefore, the semiconductor device 1 according to this first embodiment has a trench gate structure in which the gate electrode 14 and the insulating region 52 are provided in a trench formed in the semiconductor layer 2. In other examples, semiconductor device 1 may have a planar gate structure in which the gate electrode 14 and the insulating region 52 are provided on the upper surface 2b of the semiconductor layer 2.

The drift region 21 functions as the drift region of the MOSFET. In this example, the drift region 21 is provided in the cell region CR, the intermediate region MR, and the terminal region TR of the semiconductor layer b. The drift region 21 is located above the drain region 22 (above the drain electrode 11). The drift region 21 is, for example, an n- type semiconductor region. The n-type impurity concentration of the drift region 21 is, for example, between 1×10¹⁵ cm⁻³ and 2×10¹⁶ cm⁻³.

The drain region 22 functions as the drain region of the MOSFET. In this embodiment, the drain region 22 is provided in the cell region CR, the intermediate region MR, and the terminal region TR. The drain region 22 is located above the drain electrode 11 and is positioned between the drift region 21 and the drain electrode 11. The drain region 22 is in contact with the drain electrode 11 and is electrically connected to the drain electrode 11. The drain region 22 is, for example, an n+ type semiconductor region. The n-type impurity concentration of the drain region 22 is, for example, between 1×10¹⁸ cm⁻³ and 1×10²¹ cm⁻³.

The drift region 21 and the drain region 22 are both examples of a first semiconductor region. In some examples, drain region 22 may not be provided. In such a case, the drift region 21 is directly provided above the drain electrode 11, and the drain electrode 11 is electrically connected to the drift region 21. Alternatively, the drift region 21 may not be provided. In such a case, the drain region 22 is provided in the position of the drift region 21.

As shown in FIG. 4, the base region 23 functions as the base region of the MOSFET. In this example, the base region 23 is provided in the cell region CR and the intermediate region MR. The base region 23 is located above the drift region 21. The base region 23 is, for example, a p-type semiconductor region. The p-type impurity concentration of the base region 23 is, for example, between 1×10¹⁶ cm⁻³ and 1×10²⁰ cm⁻³. The base region 23 is an example of a second semiconductor region.

The source region 24 functions as the source region of the MOSFET. In this example, the source region 24 is provided in the cell region CR and is not provided in the intermediate region MR and the terminal region TR. The source region 24 is located above the base region 23. In a cross-section outside those depicted, the source region 24 is in contact with a contact portion 34 and is electrically connected to the source electrode 12 via the contact portion 34 and the conductive film 43. The source region 24 is, for example, an n+ type semiconductor region. The n-type impurity concentration of the source region 24 is, for example, between 1×10¹⁸ cm⁻³ and 1×10²²cm⁻³. The source region 24 is an example of a third semiconductor region.

The high concentration region 25 is provided in the cell region CR and the intermediate region MR. The high concentration region 25 is located above the base region 23 and contacts the lower end of a contact portion 34. The high concentration region 25 is electrically connected to the source electrode 12 via the contact portion 34 and the conductive film 43. The high concentration region 25 is, for example, a p+ type semiconductor region. That is, the impurity concentration of the high concentration region 25 is higher than the impurity concentration of the base region 23. The p-type impurity concentration of the high concentration region 25 is, for example, between 1×10¹⁸ cm⁻³ and 1×10²¹ cm⁻³. By providing the high concentration region 25, the minority carriers (in this example, holes) remaining in the base region 23 can be easily discharged to the source electrode 12 via the contact portion 34 and the conductive film 43. This improves the avalanche tolerance of the semiconductor device 1.

The guard ring region 26 is provided in the terminal region TR of the semiconductor layer 2. The guard ring region 28 is, for example, a p-type semiconductor region. The p-type impurity concentration of the guard ring region 28 is, for example, between 1×10¹⁷ cm⁻³ and 1×10¹⁹ cm⁻³. By providing the guard ring region 28, the breakdown voltage of the semiconductor device 1 can be improved.

As described above, the semiconductor device 1 according to this first embodiment includes the semiconductor layer 2, the first FP electrode group, the second FP electrode group, the gate electrode 14, the insulating region 53, the conductive film 41, the conductive film 42, and the insulating region 61. The semiconductor layer 2 includes the lower surface 2a and the upper surface 2b. The semiconductor layer 2 includes the terminal region TR extending inward from the side portion 2c connecting the lower surface 2a and the upper surface 2b, and the cell region CR located inside the semiconductor layer 2 more inward than the terminal region TR. The first FP electrode group is provided in the terminal region TR of the semiconductor layer 2 via the insulating region 51 and includes multiple FP electrodes 13a arranged in the X-axis direction and extending from the cell region CR to the terminal region TR. The second FP electrode group is provided in the terminal region TR of the semiconductor layer 2 via the insulating region 51 and includes multiple FP electrodes 13b arranged in the X-axis direction. The second FP electrode group is adjacent to the first FP electrode group in the Y-axis direction. The gate electrode 14 faces the semiconductor layer 2 in the Z-axis direction via the insulating region 52 and is arranged between the first FP electrode group and the second FP electrode group in the Y-axis direction. The insulating region 53 is provided on the upper surface 2b of the semiconductor layer 2 in the terminal region TR. The conductive film 41 is provided on the insulating region 53 and is electrically connected to multiple FP electrodes 13a included in the first FP electrode group via the contact portion 31 penetrating the insulating region 53 in the Z-axis direction. The conductive film 41 is provided on the insulating region 53 and is electrically connected to multiple FP electrodes 13b included in the second FP electrode group via the contact portion 31 penetrating the insulating region 53 in the Z-axis direction. The conductive film 42 is provided on the insulating region 53 and is positioned between the conductive film 41 electrically connected to multiple FP electrodes 13a and the conductive film 41 electrically connected to multiple FP electrodes 13b in the Y-axis direction, and is electrically connected to the gate electrode 14 via the contact portion 32 penetrating the insulating region 53 in the Z-axis direction, extending from the contact portion 32 towards the side portion 2c. The insulating region 61 is provided between the conductive film 41 electrically connected to multiple FP electrodes 13a and the conductive film 42, and between the conductive film 41 electrically connected to multiple FP electrodes 13b and the conductive film 42 in the Y-axis direction, and has a lower dielectric constant than the insulating region 53.

According to the semiconductor device 1 of this embodiment, by providing the insulating region 61 with a low dielectric constant between the conductive film 41 electrically connected to the FP electrode 13 and the conductive film 42 electrically connected to the gate electrode 14, the parasitic capacitance between the conductive film 41 and the conductive film 42 can be reduced. Therefore, the switching efficiency of the semiconductor device 1 can be improved.

In addition, according to this embodiment, the end portion 61a of the insulating region 61 on the side portion 2c side of the semiconductor layer 2 is positioned closer to the cell region CR side than the end portion 41a of the conductive film 41 on the side portion 2c side. Also, the end portion 61b of the insulating region 61 on the cell region CR side is positioned closer to the side portion 2c side than the end portion 42a of the conductive film 42 on the cell region CR side. That is, the corner portion 41c of the conductive film 41 and the corner portion 42c of the conductive film 42 are covered by the insulating region 54 with a higher dielectric constant than the insulating region 61. This can prevent the reduction of the withstand voltage (gate-source withstand voltage) between the conductive film 41 and the conductive film 42. More specifically, as shown in FIG. 2, it can reduce the occurrence of time-dependent dielectric breakdown (TDDB) due to electric field concentration between the corner portion 41c and the conductive film 42 adjacent to the corner portion 41c. Similarly, it can reduce the occurrence of TDDB due to electric field concentration between the corner portion 42c and the conductive film 41 adjacent to the corner portion 42c. Therefore, the reliability of the semiconductor device 1 can be improved. The conductive film 41 and the conductive film 42 may have a more rounded shape at the positions of the corner portions 41c and 42c than the shapes shown in FIG. 2. This can further reduce the electric field concentration at the corner portions 41c and 42c.

In this embodiment, the FP electrodes 13 in the cell region CR and the intermediate region MR were arranged in a rectangular shape. More specifically, the FP electrodes 13 were arranged along the X-axis and Y-axis directions. However, this embodiments are not limited to this, and the FP electrodes 13 may be arranged along the X-axis direction and a direction oblique to the X-axis direction. Alternatively, the FP electrodes 13 may be arranged along the Y-axis direction and oblique to the Y-axis direction. For example, in the cell region CR and the intermediate region MR, the FP electrodes 13 may be arranged in a honeycomb shape of arrayed hexagon patterns. If the FP electrodes 13 are arranged in a honeycomb shape, the planar shape of the individual FP electrodes 13 may be hexagonal, in some examples.

### The manufacturing method of the semiconductor device 1

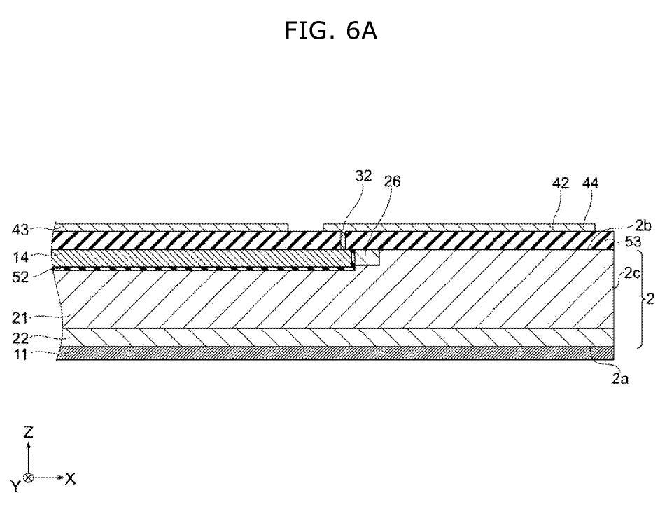

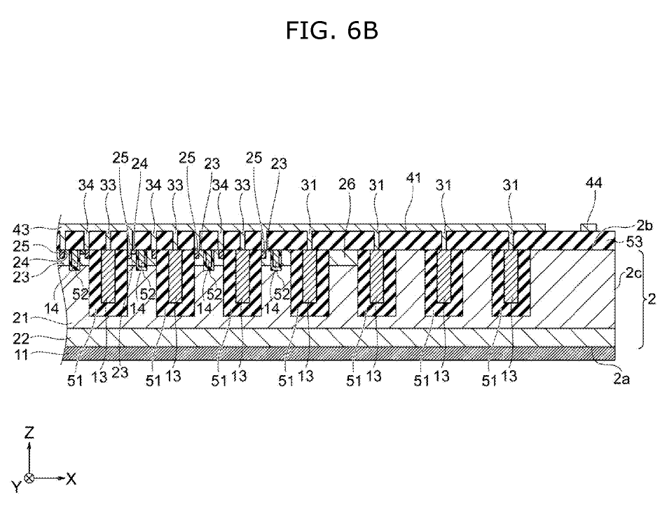

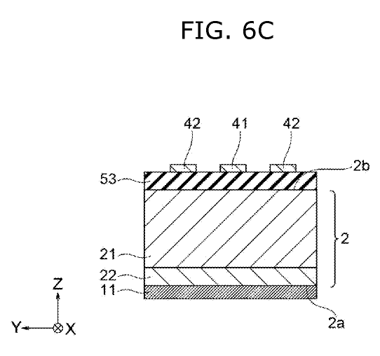

Next, with reference to FIGS. 6A to 9C, an example of the manufacturing method of the semiconductor device 1 according to a first embodiment will be described. FIGS. 6A, 7A, 8A, and 9A are diagrams corresponding to cross-sectional views along line A1-A1 in FIG. 1 for explaining an example of the manufacturing process of the semiconductor device 1. FIGS. 6B, 7B, 8B, and 9B are diagrams corresponding to cross-sectional views along line B1-B1 in FIG. 1 for explaining an example of the manufacturing process of the semiconductor device 1. FIGS. 6C, 7C, 8C, and 9C are diagrams corresponding to cross-sectional views along line C1-C1 in FIG. 1 for explaining an example of the manufacturing process of the semiconductor device 1.

First, the semiconductor device member shown in FIGS. 6A to 6C is prepared. This semiconductor device member includes the semiconductor layer 2, the drain electrode 11, the contact portions 31 to 34, the conductive films 41 to 44, and the insulating region 53. The semiconductor layer 2 is provided with the aforementioned FP electrodes 13, gate electrode 14, drift region 21, drain region 22, base region 23, source region 24, high concentration region 25, guard ring region 26, insulating region 51, and insulating region 52.

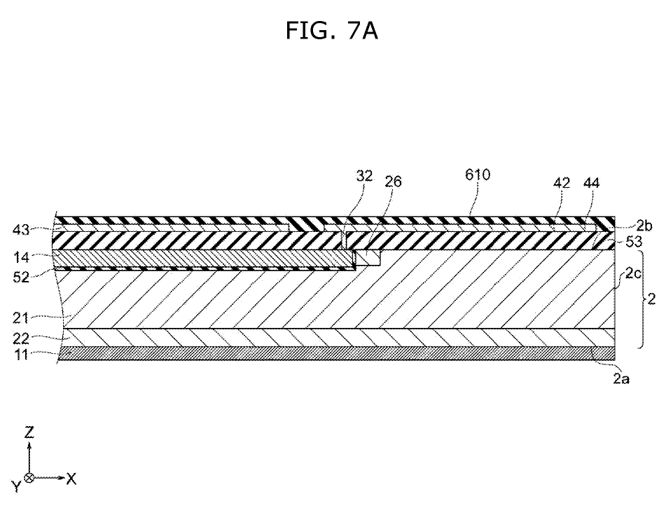

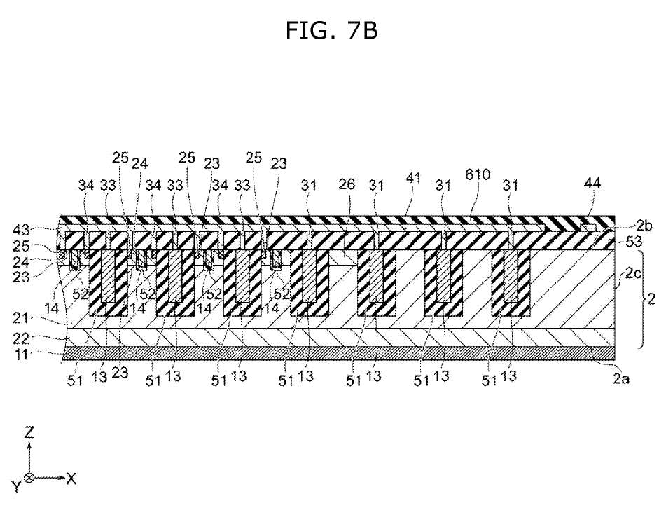

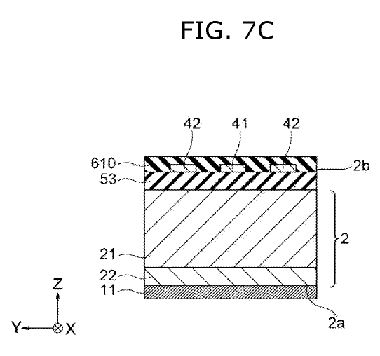

Next, as shown in FIGS. 7A to 7C, an insulating material is applied to the upper surface 2b of the semiconductor layer 2 using a device for photolithography to form the insulating region 610. The insulating material is, for example, carbon-added silicon oxide or fluorine-added silicon oxide.

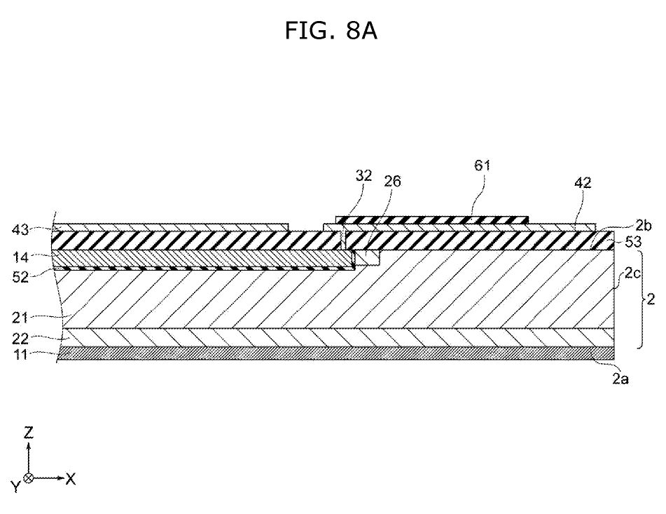

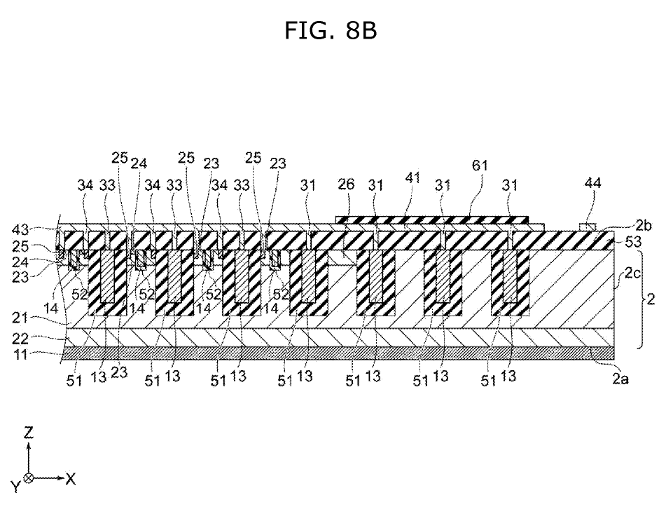

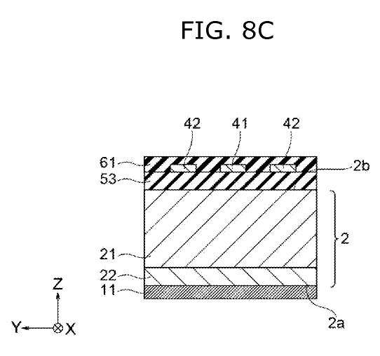

Next, as shown in FIGS. 8A to 8C, the parts of the insulating region 610 other than the insulating region 61 are removed. This process is performed as follows, for example. First, form a resist film on the upper surface of the part of the insulating region 610 corresponding to the insulating region 61. Then, remove the parts of the insulating region 610 other than the insulating region 61 by wet etching or the like using the resist film as a mask. Then, remove the resist film.

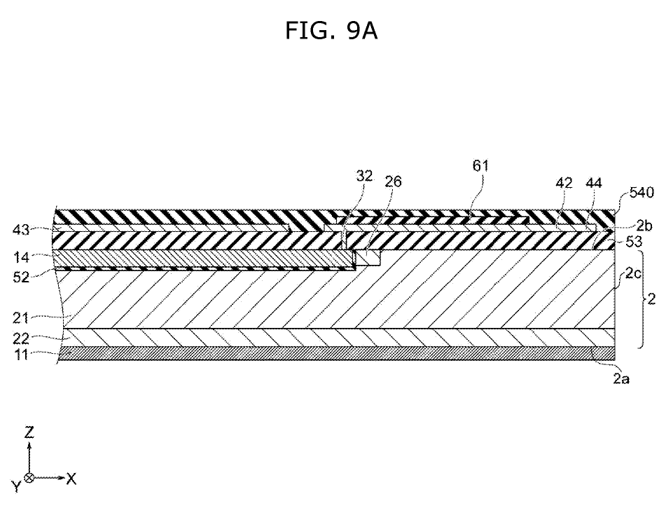

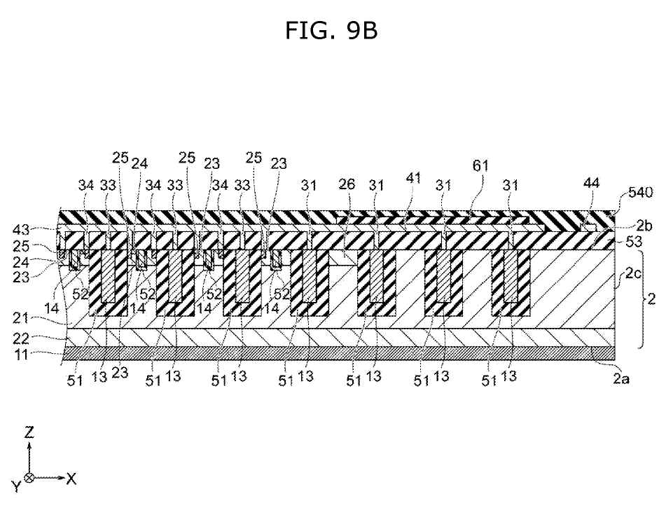

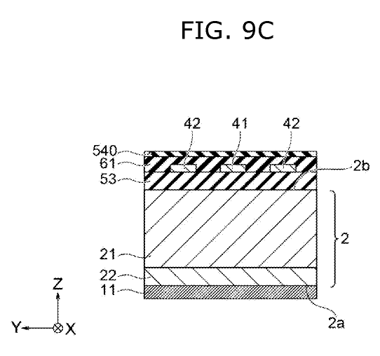

Next, as shown in FIGS. 9A to 9C, an insulating material is deposited on the upper surface 2b of the semiconductor layer 2 by chemical vapor deposition (CVD) or the like to form the insulating region 540. The insulating material is, for example, silicon oxide or silicon nitride.

Then, the parts of the insulating region 540 other than the parts corresponding to the insulating region 54 are removed by wet etching or the like. This leaves the insulating region 54. Then, the source electrode 12 is formed in the removed insulating region 540. Through these steps, the semiconductor device 1 is manufactured.

If a resist film is used as the insulating region 61, then, in the steps shown in FIGS. 7A to 7C, an organic polymer material, such as polyimide, is applied to the upper surface 2b of the semiconductor layer 2 as the insulating material. Then, in the steps shown in FIGS. 8A to 8C, an exposure and development process can be performed instead of a wet etching or the like to leave the resist as the insulating region 61.

In the above manufacturing method, the drain electrode 11 was formed on the lower surface 2a of the semiconductor layer 2 before the steps shown in FIGS. 6A to 6C. However, this is not a limitation, and the drain electrode 11 may be formed on the lower surface 2a of the semiconductor layer 2 after the steps shown in FIGS. 9A to 9C.

### SECOND EMBODIMENT

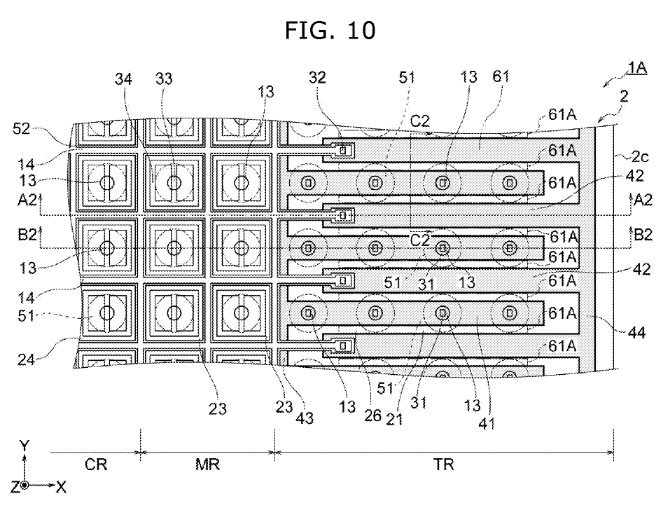

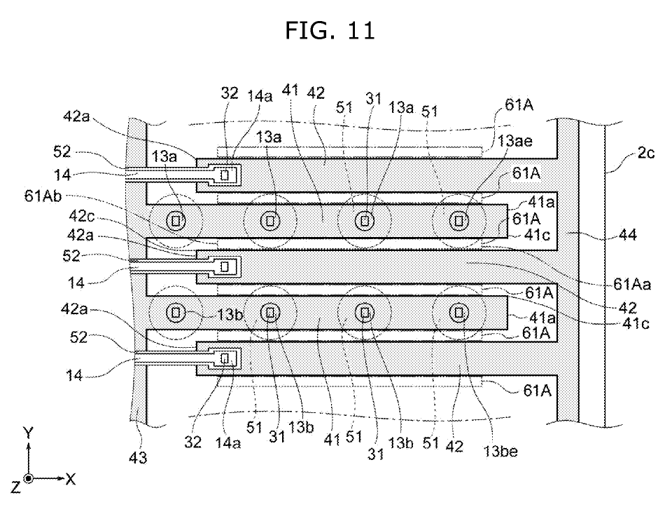

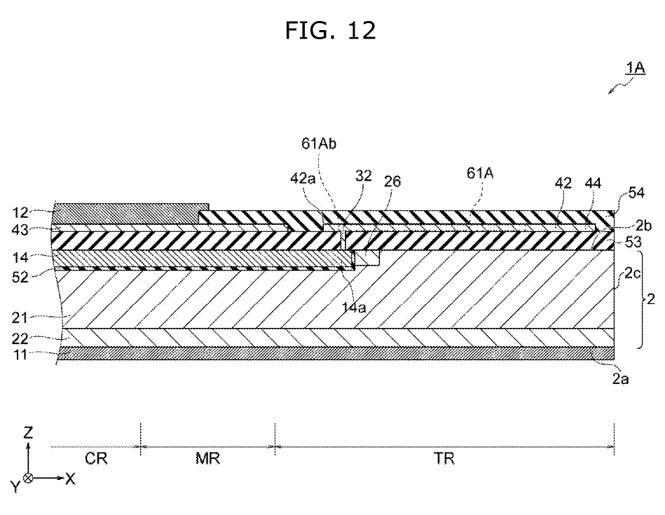

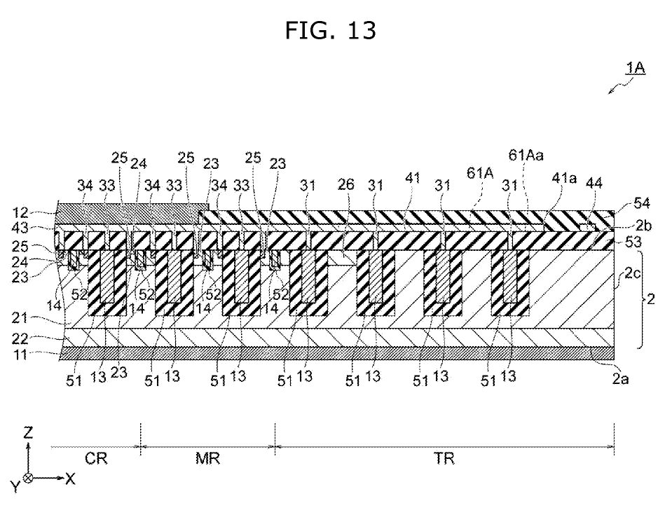

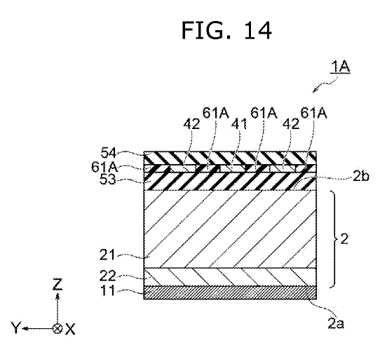

Next, with reference to FIGS. 10 to 14, a second embodiment in which the insulating region 54 is directly provided on the conductive film 41 and the conductive film 42 will be described, focusing on the differences from the first embodiment. FIG. 10 is a plan view of the semiconductor device 1A according to the second embodiment. FIG. 11 is an enlarged view of the terminal region TR in FIG. 10. FIG. 12 is a partial cross-sectional view along line A2-A2 in FIG. 10 of the semiconductor device 1A according to the second embodiment. FIG. 13 is a partial cross-sectional view along line B2-B2 in FIG. 10 of the semiconductor device 1A according to the second embodiment. FIG. 14 is a cross-sectional view along line C2-C2 in FIG. 10 of the semiconductor device 1A according to the second embodiment. In FIGS. 10 and 11, the source electrode 12, insulating region 53, and insulating region 54 are omitted from the depiction. Furthermore, in FIG. 10, the high concentration region 25 and conductive film 43 in the cell region CR and intermediate region MR are omitted from the depiction.

As shown in FIGS. 10, 11, and 14, in this second embodiment, instead of a singular insulating region 61 being provided over multiple conductive films 41 and 42 as in the first embodiment, multiple insulating regions 61A are provided between the conductive films 41 and 42 adjacent in the Y-axis direction. In this second embodiment, the upper surface of each insulating region 61A is positioned at the same height as the upper surface of the conductive films 41 and 42. Also, as shown in FIG. 14, the insulating regions 61A are not provided covering (above) the conductive films 41 and 42. Instead, the insulating region 54 is directly on the conductive films 41 and 42. That is, in this second embodiment, the insulating region 54 is in direct contact with the conductive films 41 and 42.

As shown in FIG. 11, in this second embodiment, each insulating region 61A extends in the X-axis direction and fills part of the space between the conductive films 41 and 42 otherwise adjacent to each other in the Y-axis direction. More specifically, the end portion 61Aa on the side portion 2c side of each insulating region 61A is positioned closer to the cell region CR side than the end portion 41a on the side portion 2c side of the conductive film 41. That is, there is no insulating region 61A between the corner portion 41c of the conductive film 41 and the conductive film 42 adjacent to the corner portion 41c. Also, the end portion 61Ab on the cell region CR side of each insulating region 61A is positioned closer to the side portion 2c side than the end portion 42a on the cell region CR side of the conductive film 42. That is, there is no insulating region 61A between the corner portion 42c of the conductive film 42 and the conductive film 41 adjacent to the corner portion 42c.

According to the semiconductor device 1A of this second embodiment, by directly providing the insulating region 54 on the conductive films 41 and 42, the possibility of the insulating region 54 peeling off from the semiconductor device 1A can be reduced. More specifically, the insulating region 54, which is made of a material with a high dielectric constant, has higher adhesion to the conductive films 41 and 42 compared to the insulating region 61, which is made of a material with a low dielectric constant. Therefore, for example, in the manufacturing process of the semiconductor device 1A, when a protective tape provided on the upper surface 2b of the semiconductor layer 2 is peeled off in a subsequent process after polishing the lower surface 2a, the possibility of the insulating region 54 peeling off from the upper surface of the conductive films 41 and 42 can be reduced. This can improve the yield in the manufacturing of the semiconductor device 1A, for example.

### The manufacturing method of the semiconductor device 1A

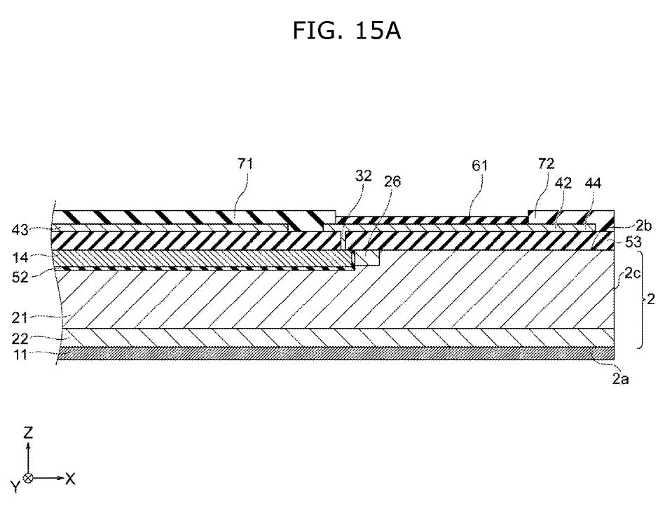

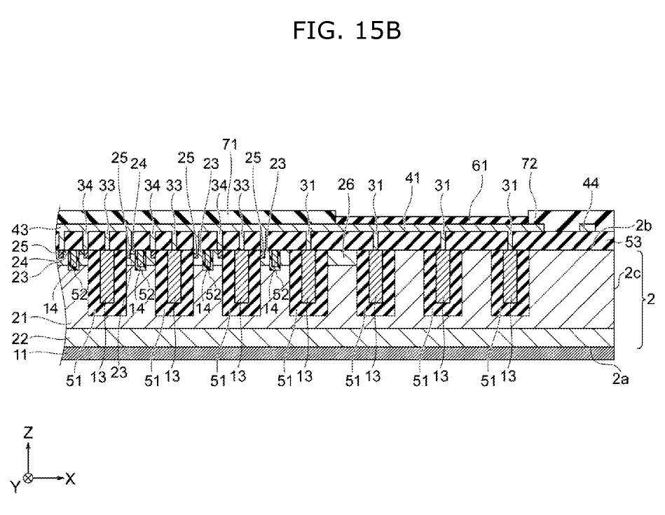

Next, with reference to FIGS. 15A and 15B, an example of the manufacturing method of the semiconductor device 1A according to this second embodiment will be described. FIG. 15A is a diagram corresponding to a cross-sectional view along line A2-A2 in FIG. 10 for explaining an example of the manufacturing process of the semiconductor device 1A. FIG. 15B is a diagram corresponding to a cross-sectional view along line B2-B2 in FIG. 10 for explaining an example of the manufacturing process of the semiconductor device 1A.

After the steps shown in FIGS. 8A to 8C, as shown in FIGS. 15A and 15B, the resist film 71 and the resist film 72 are formed on the upper surface 2b of the semiconductor layer 2. The resist film 71 covers the part of the upper surface 2b of the semiconductor layer 2 closer to the cell region CR than the insulating region 61. The resist film 71 covers the part of the upper surface 2b of the semiconductor layer 2 closer to the side portion 2c than the insulating region 61.

Then, the parts of the insulating region 61 positioned above the conductive films 41 and 42 are removed by wet etching or the like using the resist films 71 and 72 as masks. This exposes the upper surfaces of the conductive films 41 and 42. Also, the multiple insulating regions 61A remain between the conductive films 41 and 42 otherwise adjacent in the Y-axis direction. Then, the insulating region 54 and the source electrode 12 are formed as in the first embodiment. Through these steps, the semiconductor device 1A is manufactured.

### THIRD EMBODIMENT

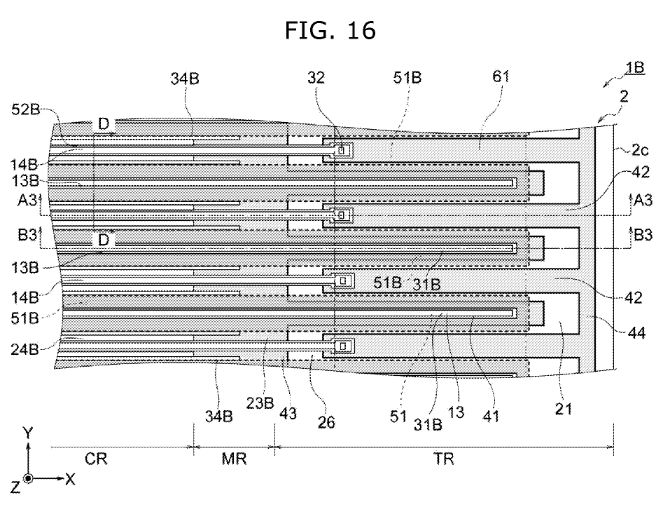

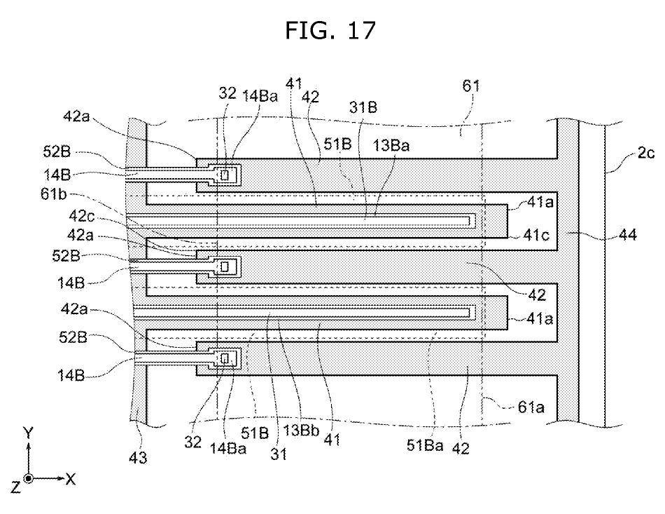

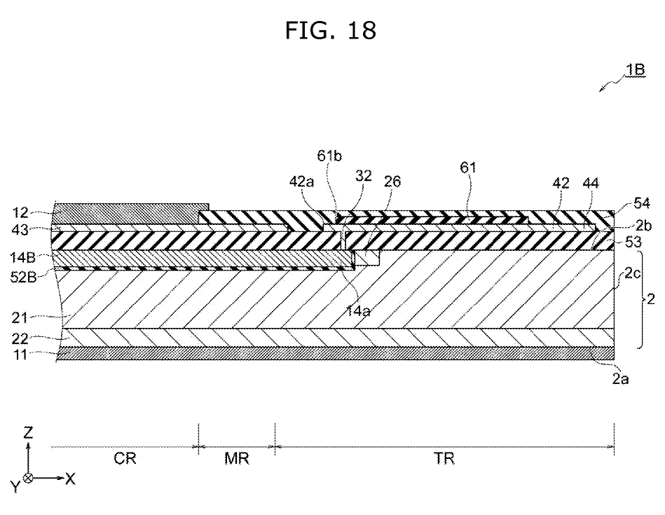

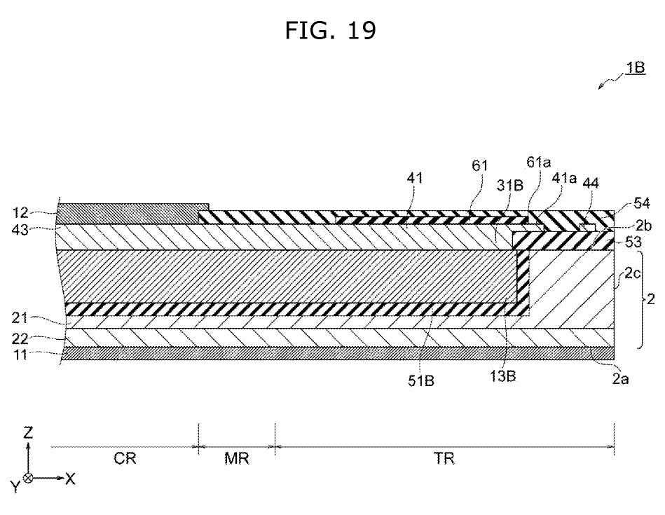

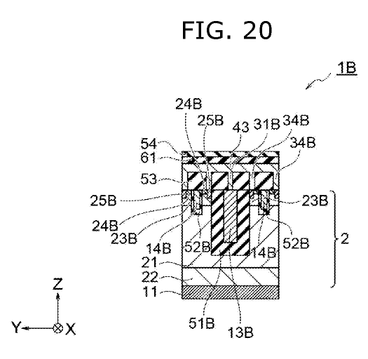

Next, with reference to FIGS. 16 to 20, a third embodiment with multiple FP electrodes 13B having a stripe shape will be described, focusing on the differences from the first embodiment. FIG. 16 is a plan view of the semiconductor device 1B according to the third embodiment. FIG. 17 is an enlarged view of the terminal region TR in FIG. 16. FIG. 18 is a cross-sectional view along line A3-A3 in FIG. 16 of the semiconductor device 1B according to the third embodiment. FIG. 19 is a cross-sectional view along line B3-B3 in FIG. 16 of the semiconductor device 1B according to the third embodiment. FIG. 20 is a cross-sectional view along line D-D in FIG. 16 of the semiconductor device 1B according to the third embodiment. In FIGS. 16 and 17, the source electrode 12, insulating region 53, and insulating region 54 are omitted from the depiction. Furthermore, in FIG. 10, the high concentration region 25B in the cell region CR and the intermediate region MR is omitted from the depiction.

First, the planar structure of the semiconductor device 1B according to this third embodiment will be described. In the plane shown in FIG. 16, the semiconductor device 1B includes the FP electrodes 13B, gate electrode 14B, base region 23B, source region 24B, contact portion 31B, and insulating regions 51B and 52B instead of the FP electrodes 13, gate electrode 14, base region 23, source region 24, contact portion 31, and insulating regions 51 and 52 in the semiconductor device 1 according to the first embodiment. Also, the semiconductor device 1B includes the contact portion 34B instead of the contact portions 33 and 34 in the semiconductor device 1 according to the first embodiment.

As shown in FIG. 16, the FP electrodes 13B have a stripe shape. In the example of FIG. 16, multiple FP electrodes 13B extending in the X-axis direction are provided. Each FP electrode 13B is arranged from the cell region CR and the intermediate region MR of the semiconductor layer 2 to the middle of the terminal region TR. Also, FP electrodes 13B are arranged at a predetermined interval along the Y-axis direction.

Insulating regions 51B are provided around each FP electrode 13B. The insulating regions 51B extend in the X-axis direction. The FP electrodes 13B and the insulating regions 51B are provided in FP trenches extending in the X-axis direction within the semiconductor layer 2. That is, the semiconductor device 1B is formed with multiple FP trenches arranged at predetermined intervals, and FP electrodes 13B and insulating regions 51B are formed within each FP trench.

In the cell region CR, high concentration regions 25B are provided to contact the insulating regions 51B, and source regions 24B are provided to contact the high concentration regions 25B. In the intermediate region MR, high concentration regions 25B are provided to contact the insulating regions 51B, and base regions 23B are provided to contact the high concentration regions 25B. In the terminal region TR, drift regions 21 or guard ring regions 26 are provided to contact the insulating regions 51B.

The gate electrode 14B is provided extending from the cell region CR and the intermediate region MR of the semiconductor layer 2 to the middle of the terminal region TR via the insulating region 52B. As shown in FIG. 16, multiple gate electrodes 14B and insulating regions 52B are provided to extend in the X-axis direction. The end of the part extending to the middle of the terminal region TR contacts a contact portion 32.

The contact portion 31B extends in the X-axis direction. The contact portion 31B electrically connects the FP electrode 13B and the conductive film 41 in the terminal region TR. The contact portion 31B also electrically connects the FP electrode 13B and the conductive film 43 in the cell region CR and the intermediate region MR. The contact portion 34B is provided to extend in the X-axis direction in the cell region CR and the intermediate region MR. The contact portion 34B contacts the source region 24B and the high concentration region 25B in the cell region CR, and the base region 23B and the high concentration region 25B in the intermediate region MR.

Next, with reference to FIG. 17, the area around the terminal region TR will be described. As shown in FIG. 17, FP electrodes 13Ba and 13Bb are provided in the terminal region TR of the semiconductor layer 2. The FP electrode 13Ba is an example of a first field plate electrode. The FP electrode 13Bb is an example of a second field plate electrode.

The FP electrode 13Ba is electrically connected to the conductive film 41. More specifically, the conductive film 41 is provided to extend in the X-axis direction above the FP electrode 13Ba. The conductive film 41 is electrically connected to the FP electrode 13Ba via a contact portion 31B. The conductive film 41 electrically connected to the FP electrode 13Ba is an example of a first conductive film.

Similarly, the FP electrode 13Bb is electrically connected to the conductive film 41. More specifically, the conductive film 41 is provided to extend in the X-axis direction above the FP electrode 13Bb. The conductive film 41 is electrically connected to the FP electrode 13Bb via a contact portion 31B. The conductive film 41 electrically connected to the FP electrode 13Bb is an example of a second conductive film.

The gate electrode 14B is arranged between the FP electrodes 13Ba and 13Bb in the Y-axis direction. The gate electrode 14B includes an end portion 14Ba. The end portion 14Ba of the gate electrode 14B is electrically connected to the conductive film 42 via a contact portion 32. More specifically, the conductive film 42 is provided above the gate electrode 14B and is positioned between the conductive film 41 (first conductive film) electrically connected to the FP electrode 13Ba and the conductive film 41 (second conductive film) electrically connected to the FP electrode 13Bb in the Y-axis direction.

Next, with reference to FIGS. 18 to 20, the cross-sectional structure of the semiconductor device 1B according to this third embodiment will be described in detail.

As shown in FIG. 20, the gate electrode 14B is provided to face the base region 23B via the insulating region 52B in the Y-axis direction.

As shown in FIG. 19, the contact portion 31B is provided on the upper surface 2b of the semiconductor layer 2 in the cell region CR, the intermediate region MR, and the terminal region TR. More specifically, the upper end of the contact portion 31B is connected to the conductive film 43 in the cell region CR and the intermediate region MR, and to the conductive film 41 in the terminal region TR. The lower end of the contact portion 31B penetrates the insulating region 53 in the Z-axis direction and contacts the FP electrode 13B. The contact portion 31B electrically connects the FP electrode 13B to the conductive films 41 and 43.

As shown in FIG. 16, the contact portion 34B is provided on the upper surface 2b of the semiconductor layer 2 in the cell region CR and the intermediate region MR. As shown in FIG. 20, the upper end of the contact portion 34B is connected to the conductive film 43. The lower end of the contact portion 34B penetrates the insulating region 53 in the Z-axis direction and contacts the source region 24B and the high concentration region 25B. The contact portion 34B electrically connects the source region 24B and the high concentration region 25B to the conductive film 43.

According to the semiconductor device 1B of this embodiment, even when multiple FP electrodes 13B with a stripe shape are provided, the parasitic capacitance between the conductive film 41 and the conductive film 42 can be reduced, similar to the semiconductor device 1 according to the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device, comprising:
a semiconductor layer with a first main surface and a second main surface, the semiconductor layer including a cell region and a terminal region surrounding the cell region;
a first field plate electrode group in the terminal region of the semiconductor layer, the first field plate electrode group including a plurality of field plate electrodes, each extending in a first direction into the semiconductor layer from the second main surface with a first insulating region therebetween, the plurality of field plate electrodes being spaced from one another along a second direction parallel to the second main surface;
a second field plate electrode group in the terminal region of the semiconductor layer, the second field plate electrode group including a plurality of field plate electrodes, each extending in the first direction into the semiconductor layer from the first main surface with a second insulating region therebetween, the plurality of field plate electrodes being spaced from one another along the second direction, the second field plate electrode group being spaced from the first field plate electrode group in a third direction intersecting the second direction and parallel to the first main surface;
a gate electrode facing the semiconductor layer via a third insulating region, the gate electrode being between the first field plate electrode group and the second field plate electrode group in the third direction;
a fourth insulating region on the second main surface in the terminal region of the semiconductor layer;
a first conductive film on the fourth insulating region and electrically connected to the field plate electrodes of the first field plate electrode group via a first contact portion;
a second conductive film on the fourth insulating region and electrically connected to the field plate electrodes of the second field plate electrode group via a second contact portion;
a third conductive film on the fourth insulating region, the third conductive film being between the first conductive film and the second conductive film in the third direction and electrically connected to the gate electrode via a third contact portion, the third conductive film extending from the third contact portion in the second direction; and
a fifth insulating region between the first conductive film and the third conductive film and the second conductive film and the third conductive film in the third direction, the fifth insulating region having a lower dielectric constant than the fourth insulating region.

2. The semiconductor device according to claim 1, wherein a first end portion of the fifth insulating region on the terminal region side is closer to the cell region side than are end portions of the first conductive film and the second conductive film on the terminal region side.

3. The semiconductor device according to claim 2, wherein the first end portion is above the first insulating region between a field plate electrode in the first field plate electrode group at an end on the terminal region side the and the semiconductor layer.

4. The semiconductor device according to claim 1, wherein a second end portion of the fifth insulating region on the cell region side is closer to the terminal region side than is an end portion of the third conductive film on the cell region side.

5. The semiconductor device according to claim 1, wherein the fifth insulating region is above the first conductive film, the second conductive film, and the third conductive film.

6. The semiconductor device according to claim 5, wherein the fifth insulating region surrounds the cell region.

7. The semiconductor device according to claim 1, further comprising:
a sixth insulating region on the first conductive film, the second conductive film, and the third conductive film, the sixth insulating region having a higher dielectric constant than the fifth insulating region.

8. The semiconductor device according to claim 1, wherein
the fourth insulating region is a silicon oxide film, and
the fifth insulating region is a material having a lower dielectric constant than the silicon oxide film.

9. The semiconductor device according to claim 8, wherein the fifth insulating region is a carbon-added silicon oxide film, a fluorine-added silicon oxide film, or a resist film.

10. The semiconductor device according to claim 1, further comprising:
a first electrode on the first main surface of the semiconductor layer;
a second electrode on the second main surface of the semiconductor layer;
a first semiconductor region of a first conductivity type in the semiconductor layer and electrically connected to the first electrode;
a second semiconductor region of a second conductivity type in the semiconductor layer above the first semiconductor region; and
a third semiconductor region of the first conductivity type in the semiconductor layer above the second semiconductor region, wherein
the first field plate electrode group is in the first semiconductor region via the first insulating region,
the second field plate electrode group is in the first semiconductor region via the second insulating region,
the gate electrode faces the second semiconductor region via the third insulating region, and
the first conductive film and the second conductive film are electrically connected to the second electrode.

11. The semiconductor device according to claim 1, wherein the field plate electrodes of the first field plate electrode group and the second field plate electrode group are arranged with respect to each other along the third direction.

12. A semiconductor device, comprising:
a semiconductor layer with a first main surface and a second main surface, the semiconductor layer including a cell region and a terminal region surrounding the cell region;
a first field plate electrode in the terminal region of the semiconductor layer, the first field plate electrode extending in a first direction into the semiconductor layer from the second main surface and in a second direction, parallel to the second main surface, from the cell region to the terminal region, a first insulating region being between the first field plate electrode and the semiconductor layer;
a second field plate electrode in the terminal region of the semiconductor layer, the second field plate electrode extending in the first direction into the semiconductor layer from the second main surface with a second insulating region therebetween, the second field plate electrode extending in the second direction from the cell region to the terminal region and being adjacent to the first field plate electrode in a third direction intersecting the second direction and parallel to the second main surface;
a gate electrode facing the semiconductor layer via a third insulating region, the gate electrode being between the first field plate electrode and the second field plate electrode in the third direction;
a fourth insulating region on the second main surface in the terminal region of the semiconductor layer;
a first conductive film on the fourth insulating region and electrically connected to the first field plate electrode via a first contact portion;
a second conductive film on the fourth insulating region and electrically connected to the second field plate electrode via a second contact portion;
a third conductive film on the fourth insulating region, the third conductive film being between the first conductive film and the second conductive film in the third direction and electrically connected to the gate electrode via a third contact portion, the third conductive film extending from the third contact portion in the second direction; and
a fifth insulating region between the first conductive film and the third conductive film and the second conductive film and the third conductive film in the third direction, the fifth insulating region having a lower dielectric constant than the fourth insulating region.

13. The semiconductor device according to claim 12, further comprising:
a first electrode on the first main surface of the semiconductor layer;
a second electrode on the second main surface of the semiconductor layer;
a first semiconductor region of a first conductivity type in the semiconductor layer and electrically connected to the first electrode;
a second semiconductor region of a second conductivity type in the semiconductor layer above the first semiconductor region; and
a third semiconductor region of the first conductivity type in the semiconductor layer above the second semiconductor region, wherein
the first field plate electrode is in the first semiconductor region with the first insulating region therebetween,
the second field plate electrode is in the first semiconductor region with the second insulating region therebetween,
the gate electrode faces the second semiconductor region via the third insulating region, and
the first conductive film and the second conductive film are electrically connected to the second electrode.

14. A semiconductor device, comprising:
a semiconductor layer with a first main surface and a second main surface separated from the first main surface in a first direction, the semiconductor layer including a cell region and a terminal region surrounding the cell region;
a first field plate electrode group in the terminal region of the semiconductor layer, the first field plate electrode group including a plurality of field plate electrodes spaced from each other along a second direction parallel to the second main surface and from the cell region to the terminal region, each field plate electrode in the first field plate electrode group being separated from the semiconductor layer by a first insulating region;
a second field plate electrode group in the terminal region of the semiconductor layer, the second field plate electrode group including a plurality of field plate electrodes spaced from each other along the second direction, the second field plate electrode group being spaced from the first field plate electrode group in a third direction intersecting the second direction and parallel to the second main surface, each field plate electrode in the second field plate electrode group being separated from the semiconductor layer by a second insulating region;
a gate electrode facing the semiconductor layer via a third insulating region, the gate electrode being between the first field plate electrode group and the second field plate electrode group in the third direction;
a fourth insulating region on the second main surface in the terminal region of the semiconductor layer;
a first conductive film on the fourth insulating region and electrically connected to the field plate electrodes of the first field plate electrode group via a first contact portion;
a second conductive film on the fourth insulating region and electrically connected to the field plate electrodes of the second field plate electrode group via a second contact portion; and
a third conductive film on the fourth insulating region, the third conductive film being between the first conductive film and the second conductive film in the third direction and electrically connected to the gate electrode via a third contact portion, the third conductive film extending from the third contact portion in the second direction.

15. The semiconductor device according to claim 14, further comprising:
a first electrode on the first main surface of the semiconductor layer;
a second electrode on the second main surface of the semiconductor layer;
a first semiconductor region of a first conductivity type in the semiconductor layer and electrically connected to the first electrode;
a second semiconductor region of a second conductivity type in the semiconductor layer above the first semiconductor region; and
a third semiconductor region of the first conductivity type in the semiconductor layer above the second semiconductor region, wherein
the first field plate electrode group is in the first semiconductor region via the first insulating region,
the second field plate electrode group is in the first semiconductor region via the second insulating region,
the gate electrode faces the second semiconductor region via the third insulating region, and
the first conductive film and the second conductive film are electrically connected to the second electrode.
